(19) United States
(12) Patent Application Publication
(10) Pub. No.: US 2008/0129431 A1
(43) Pub. Date: Jun. 5, 2008

(54) MULTIPLE OPERATION TYPE INPUT DEVICE

(76) Inventors: Mikio Onodera, Miyagi-ken (JP); Taiga Tamegai, Miyagi-ken (JP)

Correspondence Address: BRINKS HOFER GILSON & LIONE, P.O. BOX 10395, CHICAGO, IL, 60610, US

(21) Appl. No.: 11/949,997

(22) Filed: Dec. 4, 2007

(30) Foreign Application Priority Data
Dec. 4, 2006 (JP) 2006-326957

(51) Int. Cl. H01H 36/00; G01N 27/72; G01R 33/00; H01H 19/00

(52) U.S. Cl. 335/205; 324/205

(57) ABSTRACT

A multiple operation type input device includes: an operating body that is integrated with a rotating shaft A plurality of permanent magnets are provided on the operating body at the same interval in the circumferential direction thereof. A frame supports the rotating shaft. Sliders support tilting shafts of the frame; holders that supports the sliders such that the sliders can be moved in the vertical direction. A cam member is fixed to the rotating shaft. A steel ball is engaged with or disengaged from the cam member during a rotating operation, and keeps the operating body at an intermittent rotation position when the operating body is not operated. A magnetoresistive element detects a magnetic field intensity of the permanent magnets. A determining unit determines the operational state of the operating body on the basis of signals output from the magnetoresistive element. An operator can rotate, press, and tilt the operating body to input information, and the magnetoresistive element can detect signals corresponding to the rotating, pressing, and tilting operations.

### CLAIM OF PRIORITY

This application claims benefit of the Japanese Patent Application No. 2006-326957 filed on Dec. 4, 2006, the entire content of which is hereby incorporated by reference.

### BACKGROUND

1. Field of the Invention

The present invention relates to a contactless input device that detects a variation in magnetic field intensity to input information on the rotation of an operating body, and more particularly, to a multiple operation type input device that can be rotated, pressed, and tilted to input information.

2. Description of the Related Art

A contactless input device using a magnetic sensor has an advantage in that it can maintain high reliability for a long time since there is no abrasion in a contact. In addition, the contactless input device using a magnetic sensor has a lower manufacturing cost than a contactless input device using an optical sensor.

As an example of the input device using a magnetic sensor, the following rotary switch has been proposed: North and South poles are alternately arranged in an outer circumferential portion of a rotating disk; and a magnetoresistive element is provided in the vicinity of the rotating disk so as to face the outer circumferential portion, thereby detecting the rotation angle or the rotation direction of the rotating disk (for example, see JP-A-11-108689 (pp. 3 and 4, and FIG. 1)). As another example of the input device using a magnetic sensor, a tilting detecting apparatus that can detects the tilting of an operating unit on the basis of a variation in the relative position between a permanent magnet and a Hall element has been proposed (for example, see Japanese Utility Model Registration No. 3109163 (pp. 4 and 5, and FIG. 1)).

However, in recent years, input devices having multiple functions have become popular, but a contactless input device that can detect plural kinds of operations using one magnetic sensor has not been proposed. That is, when one magnetic sensor can detect different operations, such as a rotating operation and a tilting operation, it is possible to achieve a contactless input device having a simple structure, a low manufacturing cost, and multiple functions. Therefore, the contactless input device that can detect plural kinds of operations using one magnetic sensor is very useful.

### SUMMARY

According to an aspect of the invention, a multiple operation type input device includes: an operating body that is supported so as to be rotated, pressed in a direction orthogonal to the axis direction of a rotating shaft, and/or tilted in a direction in which the rotating shaft is inclined. A plurality of permanent magnets are provided on the operating body at the same interval in a circumferential direction thereof. A click unit generates a click feeling at the operating body and keeps the operating body at an intermittent rotation position in a non-operation state of the operating body. A magnetic sensor is provided in the vicinity of the operating body and detects a magnetic field intensity of each of the permanent magnets. A determining unit determines the operational state of the operating body on the basis of signals output from the magnetic sensor.

In the multiple operation type input device having the above-mentioned structure, when the operating body is rotated, a plurality of permanent magnets sequentially approach the magnetic sensor and then are separated from the magnetic sensor. Therefore, the magnetic sensor can output sine wave signals according to the rotation angle of the operating body. In addition, when the operating body is pressed in a direction orthogonal to the rotating axis thereof, the permanent magnet is extremely close to the magnetic sensor, so that the magnetic sensor can detect high magnetic field intensity. Further, when the operating body is tilted in a direction in which the rotating axis is inclined, the magnetic sensor outputs a signal having a different waveform from that during the rotating operation, according to the tilting angle or the tilting direction of the operating body. Therefore, one magnetic sensor can detect the pressing operation or the tilting operation of the operating body as well as the rotating operation.

According to a multiple operation type input device of an embodiment of the invention, when an operating body is rotated, a magnetic sensor can output sine wave signals according to the rotation angle of the operating body. In addition, when the operating body is pressed in a direction orthogonal to the axis direction of a rotating shaft, a permanent magnet is extremely close to the magnetic sensor, so that the magnetic sensor can detect high magnetic field intensity. Further, when the operating body is tilted in a direction in which the rotating shaft is inclined, the magnetic sensor outputs a signal having a different waveform from that during the rotating operation, according to the tilting angle or the tilting direction of the operating body. Therefore, one magnetic sensor can detect the pressing operation or the tilting operation of the operating body as well as the rotating operation. As a result, it is possible to achieve a contactless input device having a simple structure, a low manufacturing cost, and multiple functions.

### BRIEF DESCRIPTION OF THE DRAWINGS

FIG. 1 is a size view illustrating a multiple operation type input device according to an embodiment;

FIG. 2 is a cross-sectional view taken along the line II-II of FIG. 1;

FIG. 3 is a cross-sectional view taken along the line III-III of FIG. 2;

FIG. 4 is a cross-sectional view taken along the line IV-IV of FIG. 2;

FIG. 5 is a front view illustrating a portion of a steering wheel having the input device provided therein;

FIG. 6 is a block diagram illustrating the structure of a signal processing circuit of the input device;

FIG. 7 is a plan view illustrating sensing units of a magnetic sensor that is used for the input device;

FIG. 8 is a diagram illustrating a pressing operation of the input device; and

FIG. 9 is a diagram illustrating a tilting operation of the input device.

### DESCRIPTION OF THE EMBODIMENTS

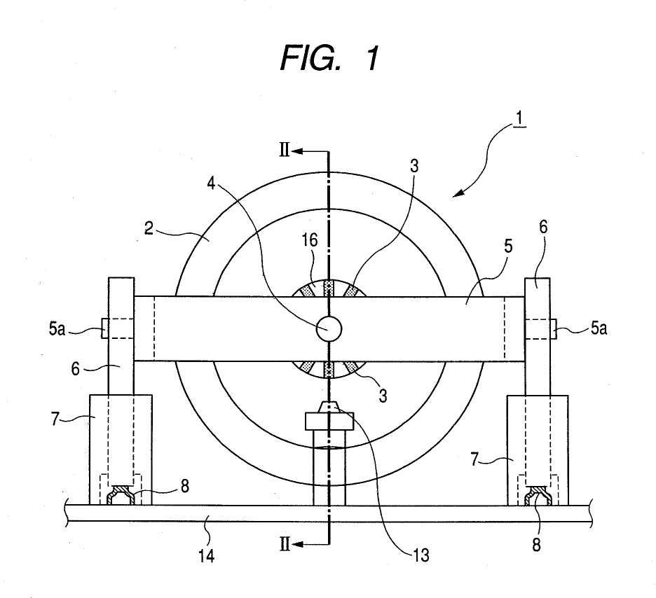

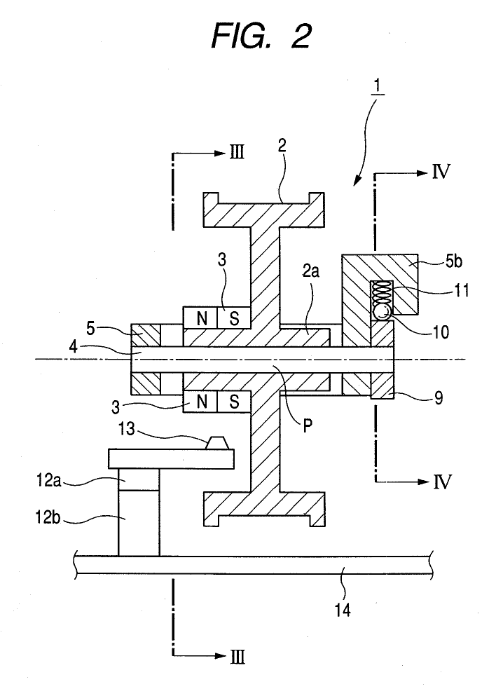

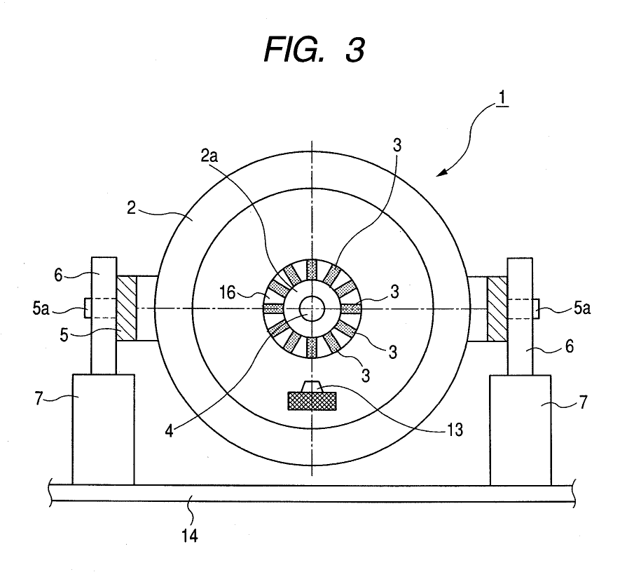

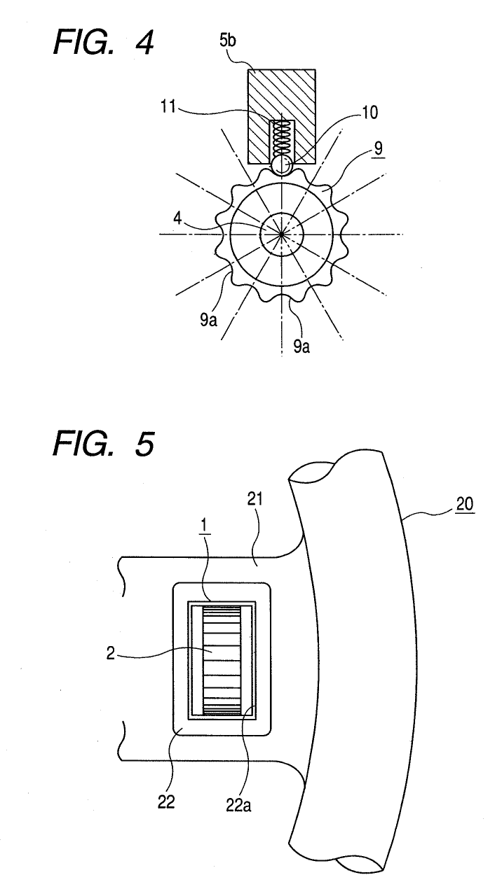

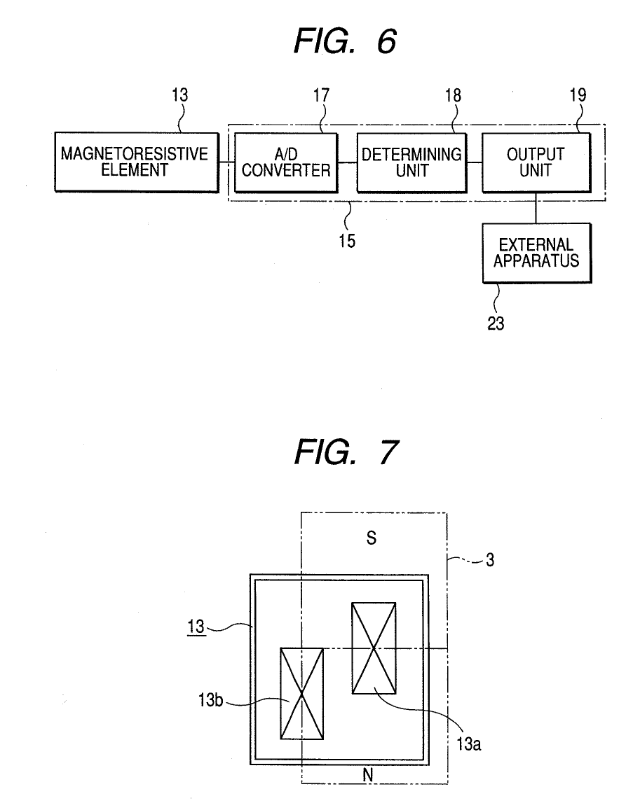

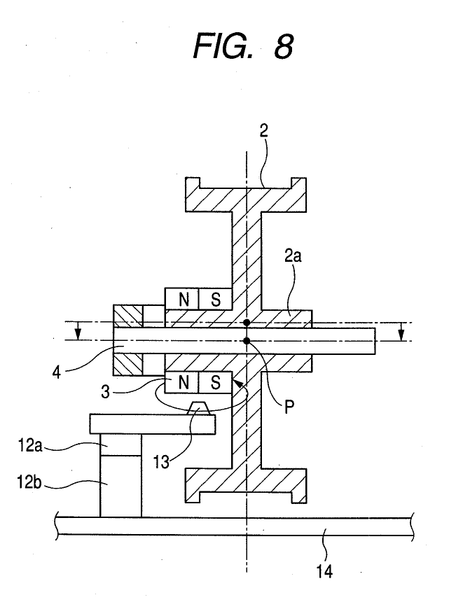

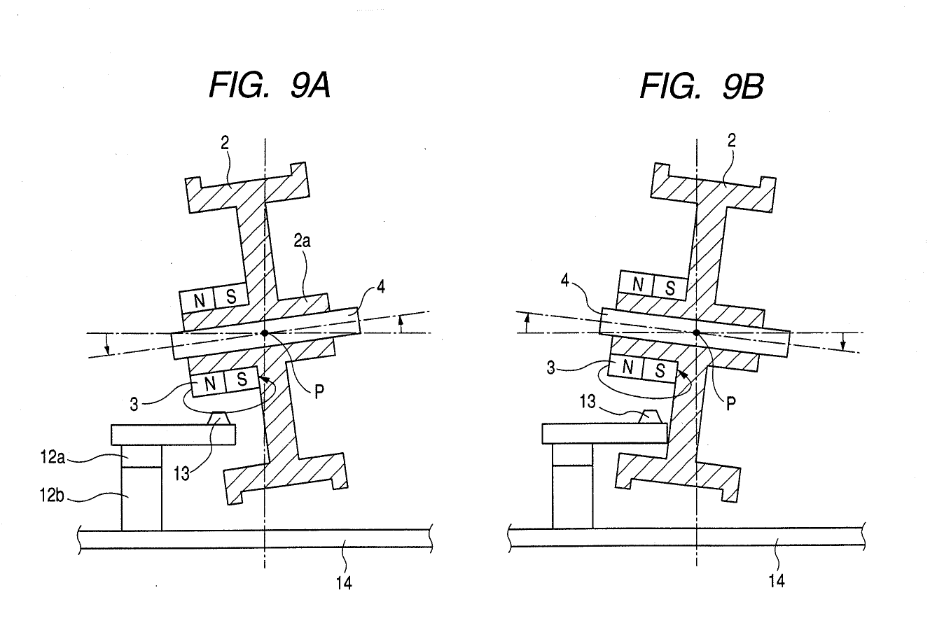

Hereinafter, exemplary embodiments will be described with reference to the accompanying drawings. FIG. 1 is a side view illustrating a multiple operation type input device according to an embodiment. FIG. 2 is a cross-sectional view taken along the line II-II of FIG. 1. FIG. 3 is a cross-sectional view taken along the line III-III of FIG. 2. FIG. 4 is a cross-sectional view taken along the line IV-IV of FIG. 2. FIG. 5 is a front view illustrating a portion of a steering wheel having the input device provided therein. FIG. 6 is a block diagram illustrating the structure of a signal processing circuit of the input device. FIG. 7 is a plan view illustrating a sensing unit of a magnetic sensor that is used for the input device. FIG. 8 is a diagram illustrating an operation for pressing the input device. FIG. 9 is a diagram illustrating an operation for tilting the input device.

A multiple operation type input device 1 according to this embodiment is used as an input device for adjusting, for example, the volume and direction of air blown from an air conditioner or the volume and quality of a sound from an audio apparatus. As shown in FIG. 5, the multiple operation type input device 1 is provided in a spoke portion 21 of a steering wheel 20 of a vehicle. The spoke portion 21 is provided with a bezel 22 having an opening portion 22a, and an operating body 2 of the multiple operation type input device 1 is exposed through the opening portion 22a, which makes it possible for an operator (driver) to operate the operating body 2 with the operator's thumb.

As shown in FIGS. 1 to 4, the multiple operation type input device 1 includes: the operating body 2 that is formed in a substantially disk shape and has a cylindrical portion 2a at its center; a plurality of permanent magnets 3 that are arranged on an outer circumferential surface of the cylindrical portion 2a; a rotating shaft 4 that is inserted and fixed to the cylindrical portion 2a; a frame 5 that has a predetermined width, surrounds the operating body 2, includes a pair of tilting shafts 5a, and supports both ends of the rotating shaft 4; a pair of sliders 6 that support the tilting shafts 5a such that the frame 5 can tilt; a pair of holders 7 that support the sliders 6 such that the sliders 6 can be moved in the vertical direction; a pair of rubber domes 8 that are provided in the corresponding holders 7 and have the sliders 6 mounted thereon; a cam member 9 that is connected to one end of the rotating shaft 4; a steel ball 10 and a coil spring 11 that are interposed between the cam member 9 and a bearing portion 5b of the frame 5; a magnetoresistive element (magnetic sensor) 13 that is mounted on a circuit board 14 with connectors 12a and 12b interposed therebetween; and a control circuit 15 (see FIG. 6) that processes signals output from the magnetoresistive element 13 and outputs the signals to an external apparatus 23.

The operating body 2 is rotatably supported by the rotating shaft 4 whose both ends are supported by the frame 5, and the rotating shaft 4 passes through the cylindrical portion 2a. In addition, a pair of tilting shafts 5 protrude from two portions of the frame 5 that are opposite to both ends of the operating body 2 in the diametric direction thereof, and the protruding direction of each of the tilting shafts 5a is orthogonal to the axis direction of the rotating shaft 4. Therefore, the operating body 2 is supported by the frame 5 such that it can be tilted by the pair of slider 6. That is, the operating body 2 can tilt in a direction in which the rotating shaft 4 is inclined in a plane that is parallel to the plane of FIG. 2, and a character P in FIG. 2 denotes a tilting center of the operating body 2. Further, the sliders 6 mounted on the rubber domes 8 can be moved in the vertical direction on the circuit board 14. Therefore, the operating body 2 is supported by the holders 7 and the rubber domes 8 such that it can be moved in the vertical direction by the frame 5 and the sliders 6.

The plurality of permanent magnets 3 are fixed to the outer circumferential surface of the cylindrical portion 2a of the operating body 2. The permanent magnets 3 are arranged at the same intervals along the circumferential direction of the operating body 2, and a gap between adjacent permanent magnets 3 serves as a non-magnetic portion 16. Each of the permanent magnets 3 is provided such that one end thereof in the longitudinal direction of the cylindrical portion 2a (the axis direction of the rotating shaft 4) serves as the North pole and the other end serves as the South pole. As shown in FIG. 2 or FIG. 9, each of the permanent magnets 3 is arranged at a position that leans from the tilting center P of the operating body 2 toward one side thereof in the tilting direction.

The magnetoresistive element 13, serving as a magnetic sensor, is used to detect the magnetic field intensity of the permanent magnets 3. The magnetoresistive element 13 is provided in the vicinity of the cylindrical portion 2a of the operating body 2 so as to face the permanent magnets 3 in the shortest range. As shown in FIG. 7, the magnetoresistive element 13 is provided with a first sensing unit 13a and a second sensing unit 13b, and the first and second sensing units 13a and 13b detect the magnetic field intensity of the same permanent magnet 3 at different positions. That is, the first sensing unit 13a slightly deviates from the second sensing unit 13b in the horizontal direction of FIG. 2 (the axis direction of the rotating shaft 4) and the horizontal direction of FIG. 3 (the direction in which the tilting shafts 5a protrude). The first sensing unit 13a is closer to the tilting center P than the second sensing unit 13b, and, when the operating body 2 rotates, detection signals of the sensing units 13a and 13b have a phase difference therebetween.

Grooves 9a are formed in the outer circumferential surface of the cam member 9 at the same interval. The cam member 9 rotates with the rotation of the rotating shaft 4, and the steel ball 10 elastically contacts with the coil spring 11 by the cam member 9 at all times. Therefore, when the rotating shaft 4 rotates, the steel ball 10 is engaged with or disengaged from the grooves 9a of the cam member 9, so that a click feeling is obtained. The cam member 9, the steel ball 10, and the coil spring 11 form a click unit of the input device 1. The number of grooves 9a is equal to the number of permanent magnets 3. When the steel ball 10 is engaged with the groove 9a, as shown in FIG. 7, the permanent magnet 3 is arranged so as to directly face the first sensing unit 13a of the magnetoresistive element 13. The outer circumferential surface of the cam member 9 is formed in a smooth waveform shape. Therefore, when the operating body 2 is not operated, the steel ball 10 is engaged with the groove 9a, and the rotation of the rotating shaft 4 is restricted. That is, when the operating body 2 is not operated, the click unit keeps the operating body 2 at a position where the operating body 2 intermittently rotates.

As shown in FIG. 6, the control circuit 15 includes an A/D converter 17 that converts analog signals output from the magnetoresistive element 13 into digital signals, a determining unit 18 that determines the operational state of the operating body 2 on the basis of the digital signals output from the A/D converter 17, and an output unit 19 that outputs the determined result output from the determining unit 18 to an external apparatus 23.

According to the multiple operation type input device 1 having the above-mentioned structure, the operator can rotate, press, and tilt the operating body 2 that is exposed through the opening portion 22a of the bezel 22 with the operator's thumb. Then, signals corresponding to the rotating, pressing, and tilting operations are output from the magnetoresistive element 13, and the determining unit 18 determines the operational state of the operating body 2 on the basis of the signals. In this way, it is possible to control the external apparatus 23 according to the operational state of the operating body 2. For example, when the operating body 2 is rotated, the plurality of permanent magnets 3 sequentially approach the magnetoresistive element 13 and are separated therefrom. The magnetic field intensity detected by the magnetoresistive element 13 varies according to the rotation angle of the operating body 2, and sign wave signals having a phase difference therebetween are output from the first and second sensing units 13a and 13b. Therefore, it is possible to detect the rotation angle and the rotation direction of the operating body 2 on the basis of the output signals of the magnetoresistive element 13. In addition, during the rotation of the operating body 2, the steel ball 10 is engaged with or disengaged from the groove 9a of the cam member 9, so that a click feeling is obtained. The operator can roughly know the rotation angle of the operating body on the basis of the click feeling. When the operating body 2 is not operated, the permanent magnet 3 directly faces the first sensing unit 13a of the magnetoresistive element 13. Therefore, immediately after the operating body is rotated, the magnetic field intensity detected by the first sensing unit 13a is gradually lowered regardless of the rotation direction of the operating body 2, but the magnetic field intensity detected by the second sensing unit 13b increases or decreases according to the rotation direction of the operating body 2.

When the operating body 2 that is in a non-operation state is pressed in a direction that is orthogonal to the axis direction of the rotating shaft 4 at a predetermined stroke, as shown in FIG. 8, the permanent magnets 3 on the magnetoresistive element 13 are extremely close to the first and second sensing units 13a and 13b. Therefore, the first and second sensing units 13a and 13b can detect considerably higher magnetic field intensity than that in the non-operation state of the operating body 2. As a result, it is possible to detect that the operating body 2 is pressed on the basis of the output signals of the magnetoresistive element 13.

As shown in FIGS. 9A and 9B, when the operating body 2 in a non-operation state is tilted, the relative positions between the permanent magnets 3 on the magnetoresistive element 13 and the first and second sensing units 13a and 13b vary according to the tilting angle and the tilting direction of the operating body 2. For example, when the operating body 2 is tilted as shown in FIG. 9A, the gaps between the permanent magnets 3 on the magnetoresistive element 13 and the first and second sensing units 13a and 13b are narrowed. However, since the distance between the first sensing unit 13a and the tilting center P is different from the distance between the second sensing unit 13b and the tilting center P, an increase in the magnetic field intensity of the second sensing unit 13b becomes more remarkable than an increase in the magnetic field intensity of the first sensing unit 13a. On the other hand, when the operating body 2 is tilted as shown in FIG. 9B, a decrease in the magnetic field intensity of the second sensing unit 13b becomes more remarkable than a decrease in the magnetic field intensity of the first sensing unit 13a. As a result, it is possible to detect the tilting direction of the operating body 2 on the basis of the output signals of the magnetoresistive element 13.

Further, since different signals are output from the magnetoresistive element 13 to the control circuit 15 during the rotating operation, the pressing operation, and the tilting operation, the determining unit 18 can clearly distinguish the rotating operation, the pressing operation, and the tilting operation. In addition, when the output value of the magnetoresistive element 13 is within a predetermined range from a reference value in the non-operation state of the operating body 2, it is determined that the operation amount of the operating body 2 is insufficient, and thus it is possible to prevent erroneous detection when each of the rotating operation, the pressing operation, and the tilting operation is interrupted or it is not completely performed.

As described above, according to this embodiment, it is possible to detect the rotating operation, the pressing operation, and the tilting operation of the operating body 2 by using the same magnetoresistive element 13, which makes it possible to achieve a contactless multiple operation type input device 1 having a simple structure, a low manufacturing cost, and multiple functions. In addition, the multiple operation type input device 1 is provided with a click unit that includes the grooves 9a of the cam member 9 that is integrally formed with operating body 2 and the steel ball 10 engaged with or disengaged from the grooves 9a, and the output of the magnetoresistive element 13 becomes the maximum during the rotating operation of the operating body 2, similar to the non-operation state of the operating body 2. Therefore, it is easy to distinguish the rotating operation from the pressing operation and the tilting operation, and to obtain a large output from the magnetoresistive element 13 during the pressing operation or the tilting operation.

Furthermore, in this embodiment, the magnetoresistive element 13, serving as the magnetic sensor, includes the first and second sensing units 13a and 13b that can detect the magnetic field intensity of the same permanent magnet 3 at different positions. Therefore, it is possible to easily determine the rotation direction of the operating body 2 during the rotating operation or the tilting direction of the operating body 2 during the tilting operation. In addition, each of the permanent magnets 3 is arranged at a position that deviates from the tilting center P of the operating body 2 to one side in the tilting direction. Therefore, it is possible to easily determine the tilting direction of the operating body 2 during the tilting operation.

Further, in the above-described embodiment, the multiple operation type input device that can be rotated, pressed, and tilted has been described above, but the invention is not limited thereto. For example, the input device may only be rotated and pressed, or it may only be rotated and tilted. In addition, the input device may be tilted in one direction. Furthermore, both ends of each of the permanent magnets 3 may be provided in the outer circumferential direction of the operating body 2, or the magnetoresistive element 13 may be provided at a position opposite to the lower end of the operating body 2. Further, magnetic sensors other than the magnetoresistive element may be used.

1. A multiple operation type input device comprising:
an operating body that is supported so as to be rotated, pressed in a direction orthogonal to the axis direction of a rotating shaft, and/or tilted in a direction in which the rotating shaft is inclined;
a plurality of permanent magnets that are provided on the operating body at the same interval in a circumferential direction thereof,
a click unit that generates a click feeling at the operating body and keeps the operating body at an intermittent rotation position in a non-operation state of the operating body;
a magnetic sensor that is provided in the vicinity of the operating body and detects a magnetic field intensity of each of the permanent magnets; and
a determining unit that determines the operational state of the operating body on the basis of signals output from the magnetic sensor.

2. The multiple operation type input device according to claim 1,
wherein the positional relationship between the magnetic sensor and the permanent magnets is established such that the output of the magnetic sensor is lowered, when the operating body is rotated from the intermittent rotation position.

3. The multiple operation type input device according to claim 1,
wherein the magnetic sensor includes a plurality of sensing units that can detect the magnetic field intensity of the same permanent magnet at different positions.

4. The multiple operation type input device according to claim 2,
wherein the magnetic sensor includes a plurality of sensing units that can detect the magnetic field intensity of the same permanent magnet at different positions.

5. The multiple operation type input device according to claim 1,
wherein, when the operating body is pressed, the permanent magnet is closest to the magnetic sensor.

6. The multiple operation type input device according to claim 2,
wherein, when the operating body is pressed, the permanent magnet is closest to the magnetic sensor.

7. The multiple operation type input device according to claim 1,
wherein the permanent magnet is provided at a position that deviates from a tilting center of the operating body to one side in a tilting direction, when the operating body is tilted.

8. The multiple operation type input device according to claim 2,
wherein the permanent magnet is provided at a position that deviates from a tilting center of the operating body to one side in a tilting direction, when the operating body is tilted.
